(19) United States
(12) Patent Application Publication
(10) Pub. No.: US 2013/0161079 A1
(43) Pub. Date: Jun. 27, 2013

(54) MULTI-LAYER WIRING SUBSTRATE AND MANUFACTURING METHOD THEREOF

(71) Applicant: NGK SPARK PLUG CO., LTD., Nagoya-shi (JP)

(72) Inventors: Shinnosuke MAEDA, Nagoya-shi (JP); Tetsuo SUZUKI, Takahama-shi (JP); Takuya HANDO, Inuyama-shi (JP); Atsuhiko SUGIMOTO, Kagamigahara-shi (JP); Satoshi HIRANO, Chita-gun (JP); Hajime SAIKI, Cupertino, CA (US)

(73) Assignee: NGK SPARK PLUG CO., LTD., Nagoya-shi (JP)

(21) Appl. No.: 13/721,402

(22) Filed: Dec. 20, 2012

(30) Foreign Application Priority Data
Dec. 22, 2011 (JP) 2011-281280
Sep. 28, 2012 (JP) 2012-217107

(51) Int. Cl. H05K 3/46; H05K 1/02

(52) U.S. Cl. CPC H05K 3/4623; H05K 1/0298
USPC 174/255; 156/253

(57) ABSTRACT

Embodiments of the presently-disclosed subject matter include a multilayer wiring substrate including a first laminated structure that includes at least one conductive layer and at least one resin insulating layer; a core substrate that includes a reinforced fiber and that is laminated on the first laminated structure; and a second laminated structure that includes at least one conductive layer and at least one resin insulating layer and that is formed on the core substrate; and a plurality of via conductors which penetrate the first laminated structure, the core substrate, and the second laminated structure in the thickness direction, wherein the plurality of via conductors all expand in diameter in one direction, and the reinforced fiber is located above a center of the core substrate in the thickness direction.

### CROSS REFERENCE TO RELATED APPLICATIONS

The present application claims priority from Japanese Patent Application No. 2011-281280, which was filed on Dec. 22, 2011, and Japanese Patent Application No. 2012-217107, which was filed on Sep. 28, 2012, the disclosure of which are herein incorporated by reference in their entirety.

### BACKGROUND OF THE INVENTION

1. Field of the Invention

The present invention relates to a multilayer wiring substrate and a manufacturing method thereof.

2. Description of Related Art

In general, as a package in which electronic components are mounted, a multilayer wiring substrate in which a built-up layer is formed by alternately laminating a resin insulating layer and a conductive layer on both sides of a core substrate has been used (JP-A-11-233937). In the multilayer wiring substrate, the core substrate is formed of, for example, resin including glass fiber, and has a role of reinforcing the built-up layer due to a high rigidity. However, since the core substrate is formed to be thick, it becomes an obstacle of miniaturization of the multilayer wiring substrate. Accordingly, in recent years, the miniaturization of the multilayer wiring substrate has been performed by making the core substrate thin.

On the other hand, when the core substrate becomes thin, there has been a problem in that the strength of an assembly (substrate during a manufacturing processing that becomes a multilayer wiring substrate) in a manufacturing process including the core substrate is decreased, it is difficult to transport the core substrate or the assembly horizontally, and the core substrate or the assembly is damaged by being in contact with the transport equipment when being transported. In addition, in each manufacturing process, when performing a predetermined manufacturing process by fixing the core substrate or the assembly, there has been a problem in that the core substrate or the assembly is warped, and it is difficult to accurately perform a process, for example, a plating process, or the like. As a result, there has been a problem in that, when making the thickness of the core substrate thin in the multilayer wiring substrate including the core substrate, manufacturing yield is decreased.

From such a viewpoint, a so-called coreless multilayer wiring substrate has been proposed (JP-A-2009-289848 and JP-A-2007-214427) which has a structure in which the core substrate is not provided, which is suitable for miniaturization, and in which transmission performance of a high frequency signal can be improved. Such a desired coreless multilayer wiring substrate can be obtained, for example, by forming a built-up layer on a support board of which the surface is provided with a separation sheet which is formed by laminating two metal films which can be separated, and then by separating the built-up layer from a support body by separating the built-up layer from a separation interface of the separation sheet, thereby obtaining a desired multilayer wiring substrate.

However, the above described coreless multilayer wiring substrate has problems in that the strength thereof is weak, careful handling is needed, and use thereof is limited, since there is no core layer therein.

### BRIEF SUMMARY OF THE INVENTION

An object of the present invention is to provide a multilayer wiring substrate and a manufacturing method thereof in which miniaturization can be performed by making a core substrate thin without decreasing manufacturing yield, the multilayer wiring substrate having a laminated structure in which at least one conductive layer and at least one resin insulation layer are alternately laminated on both surfaces of the core substrate.

An aspect of the present invention relates to a multilayer wiring substrate that includes a first laminated structure including at least one conductive layer and at least one resin insulating layer; a core substrate that includes a reinforced fiber and that is laminated on the first laminated structure; a second laminated structure that includes at least one conductive layer and at least one resin insulating layer and that is formed on the core substrate; and a plurality of via conductors that penetrate the at least one resin insulating layer of the first laminated structure, the core substrate, and the at least one resin insulating layer of the second laminated structure, wherein the plurality of via conductors all expand in diameter in the same direction, and wherein the reinforced fiber is located above a center of the core substrate in the thickness direction.

Another aspect of the present invention relates to a manufacturing method of a multilayer wiring substrate which includes forming, on a support board, a first laminated structure that includes at least one conductive layer and at least one resin insulating layer; forming, on the first laminated structure, a core substrate that includes a reinforced fiber by laminating the core substrate on the first laminated structure; forming, on the core substrate, a second laminated structure that includes at least one conductive layer and at least one resin insulating layer; and forming a plurality of via conductors that penetrate the resin insulating layer of the first laminated structure, the core substrate, and the resin insulating layer of the second laminated structure, wherein the plurality of via conductors are all formed to expand in diameter in the same direction, and wherein the reinforced fiber is located above a center of the core substrate in the thickness direction.

According to the present invention, a manufacturing method of a so-called coreless multilayer wiring substrate forms a laminated structure in which at least one conductive layer and at least one resin insulating layer are laminated on a support board, the core substrate is also laminated along with the above described laminated structure, and an additional laminated structure having the same configuration is further laminated on the core substrate. After forming the laminated structure on the support board in the above described manner, the support board is eliminated so that the final configuration is one in which the core substrate is inserted into the laminated structure which is formed by at least one conductive layer and at least one resin insulating layer, that is, a multilayer wiring substrate having the core substrate is formed in order to eliminate the support board.

In the present invention, as described above, since the manufacturing method of the coreless multilayer wiring substrate is used when manufacturing the multilayer wiring substrate having the core substrate with the thickness of 200 μm or less, in the manufacturing process thereof, the laminated structure or the core substrate is formed on the support board. Accordingly, even when the thickness of the core substrate is made thin, strength of assembly is not decreased by making the thickness of the support board sufficiently thick in the manufacturing process.

Accordingly, it is possible to perform horizontal transportation of the assembly during manufacture, and to avoid a problem in that the core substrate or the assembly is damaged when the assembly comes into contact with transport equipment at the time of transporting. In addition, it is also possible to avoid a problem in that, when performing a predetermined manufacturing process with fixing the assembly, the assembly is warped so that it is difficult to accurately perform a process, for example, a plating process, or the like. For this reason, it is possible to obtain a multilayer wiring substrate having a thin core substrate with a high yield, and to miniaturize the multilayer wiring substrate having the core substrate.

The above described method in the present invention is not limited to manufacturing of a multilayer wiring substrate including a core substrate which has a structure in which manufacturing yield is decreased since the core substrate is thin, and the core substrate, or assembly in a manufacturing process is warped in an ordinary manufacturing method, and can be applied to a case in which the core substrate is thick, and it is possible to manufacture a multilayer wiring substrate including the core substrate, with a high yield, even in the ordinary manufacturing method.

In the present invention, a plurality of via conductors which penetrate the above described resin insulating layer of the first laminated structure, the core substrate, and the resin insulating layer of the second laminated structure in the thickness direction are all formed by being expanded in diameter in one direction therein.

In addition, in the present invention, in the core substrate including the reinforced fiber, the reinforced fiber is located above the center in the thickness direction of the core substrate (i.e., the reinforced fiber is located closer to the second laminated structure than it is to the first laminated structure).

In general, the reinforced fiber is included at the center portion of the core substrate in the thickness direction, however, as described above, when the thickness of the core substrate becomes thin, the included reinforced fiber comes closer to the conductive layer on the uppermost layer of the first laminated structure which is located at the lower side of the core substrate, and comes into contact therewith. As a result, migration of the conductive layer through the reinforced fiber occurs when the conductive layer conducts. Specifically, when a hygroscopic property of the core substrate is particularly high, an element forming the conductive layer is ionized, and the ions migrate through the reinforced fiber. For this reason, there may be a case in which electrical insulation properties between patterns of the conductive layer which are adjacent decreases, and the conductive layer can not sufficiently function as a wiring layer, or a pad.

However, in the present invention, as described above, the reinforced fiber in the core substrate is located above the center of the core substrate in the thickness direction. Accordingly, since the reinforced fiber which is included in the core substrate is separated from the uppermost conductive layer of the first laminated structure which is located on the lower side of the core substrate, and does not come into contact with the conductive layer, it is possible to prevent migration of the conductive layer through the reinforced fiber when the conductive layer conducts.

As described above, in the present invention, in the multilayer wiring substrate including the laminated structure in which at least one conductive layer, and at least one resin insulating layer are alternately laminated on both surfaces of the core substrate, it is possible to provide a multilayer wiring substrate in which the core substrate is thin and which can be miniaturized without decreasing the yield thereof, and a manufacturing method thereof.

### BRIEF DESCRIPTION OF THE DRAWINGS

FIG. 1 is a plan view of a multilayer wiring substrate according to an embodiment.

FIG. 2 is a plan view of a multilayer wiring substrate according to the embodiment.

FIG. 3 is a diagram which illustrates the multilayer wiring substrate in FIGS. 1 and 2 by enlarging a part of a cross section taken along line I-I of the multilayer wiring substrate.

FIG. 4 is a diagram which illustrates a third resin insulating layer (core substrate) of the multilayer wiring substrate illustrated in FIG. 3 by enlarging a part thereof.

FIG. 5 is a process drawing of a method of manufacturing the multilayer wiring substrate according to the embodiment.

FIG. 6 is a process drawing of the method of manufacturing the multilayer wiring substrate according to the embodiment.

FIG. 7 is a process drawing of the method of manufacturing the multilayer wiring substrate according to the embodiment.

FIG. 8 is a process drawing of the method of manufacturing the multilayer wiring substrate according to the embodiment.

FIG. 9 is a process drawing of the method of manufacturing the multilayer wiring substrate according to the embodiment.

FIG. 10 is a process drawing of the method of manufacturing the multilayer wiring substrate according to the embodiment.

FIG. 11 is a process drawing of the method of manufacturing the multilayer wiring substrate according to the embodiment.

FIG. 12 is a process drawing of the method of manufacturing the multilayer wiring substrate according to the embodiment.

FIG. 13 is a process drawing of the method of manufacturing the multilayer wiring substrate according to the embodiment.

FIG. 14 is a process drawing of the method of manufacturing the multilayer wiring substrate according to the embodiment.

FIG. 15 is a process drawing of the method of manufacturing the multilayer wiring substrate according to the embodiment.

FIG. 16 is a process drawing of the method of manufacturing the multilayer wiring substrate according to the embodiment.

FIG. 17 is a process drawing of the method of manufacturing the multilayer wiring substrate according to the embodiment.

FIG. 18 is a process drawing of the method of manufacturing the multilayer wiring substrate according to the embodiment.

FIG. 19 is a process drawing which illustrates a modified example of the method of manufacturing the multilayer wiring substrate according to the embodiment.

FIG. 20 is a process drawing which illustrates a modified example of the method of manufacturing the multilayer wiring substrate according to the embodiment.

### DETAILED DESCRIPTION OF EXEMPLARY EMBODIMENTS OF THE INVENTION

Exemplary embodiments of the present invention will next be described with reference to drawings. However, the exemplary embodiments to be described below is a mere example of an application of the technical concept of the present invention. The contents of the exemplary embodiments should not be construed as limiting the invention.

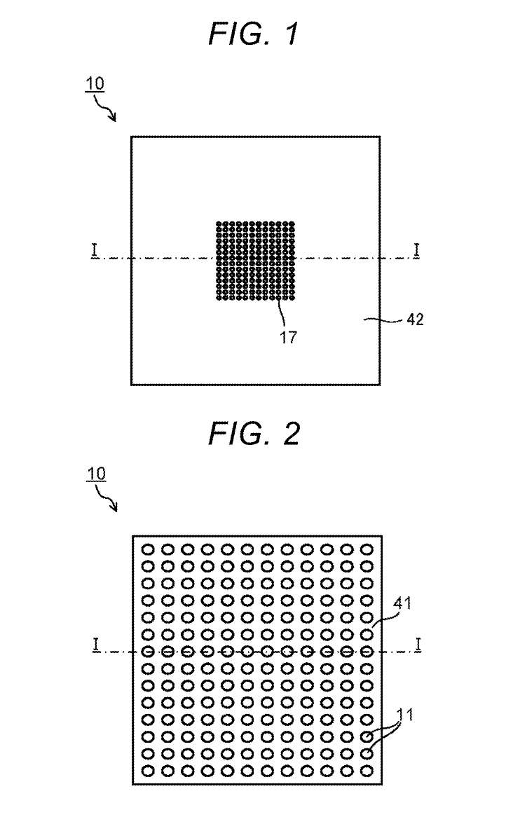

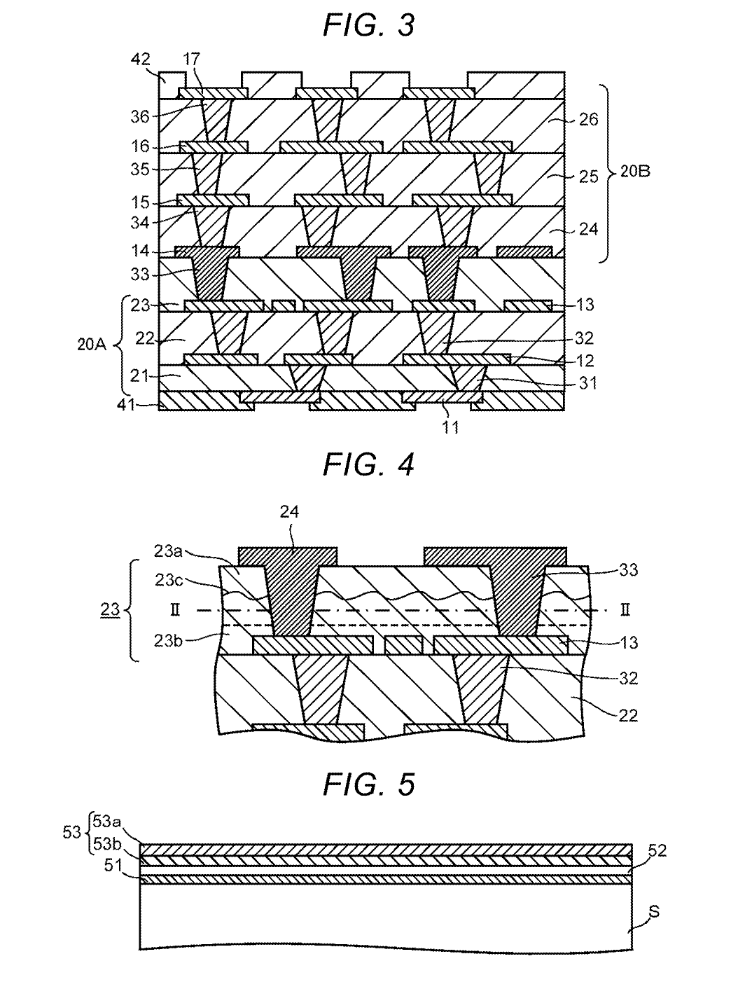

First, an example of a multilayer wiring substrate which is manufactured using a method of the present invention will be described. FIGS. 1 and 2 are plan views of a multilayer wiring substrate according to the embodiment. FIG. 1 illustrates the multilayer wiring substrate from the top, and FIG. 2 illustrates the multilayer wiring substrate from below. In addition, FIG. 3 is a diagram which illustrates the multilayer wiring substrate which is illustrated in FIGS. 1 and 2 by enlarging a part of a cross section taken along line I-I thereof, and FIG. 4 is a diagram which illustrates a third resin insulating layer of the multilayer wiring substrate illustrated in FIG. 3 by enlarging a part thereof.

However, the multilayer wiring substrate denoted below is an example for clarifying characteristics of the present invention, and is not particularly limited when the multilayer wiring substrate has a configuration in which the core substrate is interposed between the first laminated structure and the second laminated structure including at least one conductive layer and at least one resin insulating layer which are alternately laminated.

In a multilayer wiring substrate 10 which is illustrated in FIGS. 1 to 4, first conductive layer 11 to seventh conductive layer 17, and first resin insulating layer 21 to sixth resin insulating layer 26 are alternately laminated.

Specifically, a first resin insulating layer 21 is laminated on the first conductive layer 11, a second conductive layer 12 is laminated on the first resin insulating layer 21, a second resin insulating layer 22 is laminated on the second conductive layer 12, and a third conductive layer 13 is laminated on the second resin insulating layer 22. In addition, a third resin insulating layer 23 is laminated on the third conductive layer 13, a fourth conductive layer 14 is formed on the third resin insulating layer 23, a fourth resin insulating layer 24 is formed on the fourth conductive layer 14, and a fifth conductive layer 15 is laminated on the fourth resin insulating layer 24. Further, a fifth resin insulating layer 25 is laminated on the fifth conductive layer 15, a sixth conductive layer 16 is laminated on the fifth resin insulating layer 25, a sixth resin insulating layer 26 is laminated on the sixth conductive layer 16, and the seventh conductive layer 17 is laminated on the sixth resin insulating layer 26.

In addition, the first conductive layer 11 to the seventh conductive layer 17 are formed by a good electricity conductor such as copper, and the first resin insulating layer 21, the second resin insulating layer 22, and the fourth resin insulating layer 24 to the sixth resin insulating layer 26 are formed by a composition of a thermosetting resin including silica filler or the like as necessary, and the third resin insulating layer 23 comprises a plate shape core substrate which is formed by a heat-resistance resin plate (for example, bismaleimide-triazine resin plate), a fiber-reinforced resin plate (for example, glass-fiber-reinforced epoxy resin), or the like.

In addition, a first resist layer 41 is formed on the first conductive layer 11 so that a portion of the first conductive layer 11 is exposed, and a second resist layer 42 is formed on the seventh conductive layer 17 so that a portion of the seventh conductive layer 17 is exposed.

The portion of the first conductive layer 11 which is exposed from the first resist layer 41 functions as a rear surface land (LGA pad) for connecting the multilayer wiring substrate 10 to a mother board, and is arranged in a rectangular shape at the rear surface of the multilayer wiring substrate 10. The portion of the seventh conductive layer 17 which is exposed from the second resist layer 42 functions as a pad (FC pad) for performing a flip chip connecting of a semiconductor element or the like, which is not shown with respect to the multilayer wiring substrate 10, forms a mounting region for the semiconductor element, and is arranged in a rectangular shape at substantially the center portion of the surface of the multilayer wiring substrate 10.

A first via conductor 31 is formed in the first resin insulating layer 21, and the first conductive layer 11 and the second conductive layer 12 are conducted through the first via conductor 31. A second via conductor 32 is formed in the second resin insulating layer 22, and the second conductive layer 12 and the third conductive layer 13 are conducted through the second via conductor 32. Similarly, a third via conductor 33 is formed in the third resin insulating layer 23, and the third conductive layer 13 and the fourth conductive layer 14 are conducted through the third via conductor 33, and a fourth via conductor 34 is formed in the fourth resin insulating layer 24, and the fourth conductive layer 14 and the fifth conductive layer 15 are conducted through the fourth via conductor 34. In addition, a fifth via conductor 35 is formed in the fifth resin insulating layer 25, and the fifth conductive layer 15 and the sixth conductive layer 16 are conducted through the fifth via conductor 35, and a sixth via conductor 36 is formed in the sixth resin insulating layer 26, and the sixth conductive layer 16 and the seventh conductive layer 17 are conducted through the sixth via conductor 36.

According to the embodiment, the first conductive layer 11 to the third conductive layer 13, the first resin insulating layer 21 and the second resin insulating layer 22, and the first via conductor 31 and the second via conductor 32 form a first laminated structure 20A, and the fourth conductive layer 14 to the seventh conductive layer 17, the fourth resin insulating layer 24 to the sixth resin insulating layer 26, and the fourth via conductor 34 to the sixth via conductor 36 forma second laminated structure 20B.

In addition, through it is not attached with a reference numeral particularly, portions of the first conductive layer 11 to seventh conductive layer 17 which are connected to the first via conductor 31 to sixth via conductor 36 form via lands (via pads), and portions of first conductive layer 11 to seventh conductive layer 17 which are not connected to the first via conductor 31 to sixth via conductor 36 form wiring layers.

In addition, it is possible to set the size of the multilayer wiring substrate 10, for example, to 200 mm×200 mm×0.4 mm.

As illustrated in FIG. 4, according to the embodiment, the third resin insulating layer 23 has a configuration in which a resin insulating layer 23a which includes a reinforced fiber 23c at the center in the thickness direction configuring the original core substrate is laminated on the first laminated structure 20A (second resin insulating layer 22) through an additional resin insulating layer 23b which is located below the resin insulating layer 23a. As a result, since the resin insulating layer 23a is lifted in the thickness direction of the third resin insulating layer 23 by the additional resin insulating layer 23b, the reinforced fiber 23c is located above the center portion II-II of the insulating layer 23 in the thickness direction.

Accordingly, the reinforced fiber 23c which is included in the third resin insulating layer 23 is separated from and does not come into contact with the third conductive layer 13 of the first laminated structure 20A which is located downward, and it is possible to suppress a migration of the third conductive layer 13. Specifically, when a hygroscopic property of the third resin insulating layer 23 is particularly high, it is possible to suppress an element forming the third conductive layer 13 from being ionized, and to suppress the ions migrating through the reinforced fiber 23c. For this reason, it is possible to maintain the electrical insulation property between patterns adjacent to each other in the third conductive layer, and to sufficiently function as the wiring layer, or the pad of the third conductive layer 13.

In addition, according to the embodiment, in the first and second resin insulating layers 21 and 22 which form the first laminated structure 20A, the third resin insulating layer 23 that forms the core substrate, and the fourth resin insulating layer 24, fifth resin insulating layer 25, and the sixth resin insulating layer 26 which form the second laminated structure 20B, the first to sixth via conductors 31 to 36 which penetrate the above in the thickness direction are all formed in the same direction, specifically, are formed with an upward enlarging diameter. In other words, the via conductors 31 to 36 can have a larger diameter on a top side thereof than on a bottom side thereof.

Subsequently, a manufacturing method of the multilayer wiring substrate 10 which is illustrated in FIGS. 1 to 4 will be described. FIGS. 5 to 18 are process drawings of a manufacturing method of the multilayer wiring substrate 10 according to the embodiment. In addition, the process drawings illustrated in FIGS. 5 to 18 correspond to the cross-sectional view of the multilayer wiring substrate 10 which is illustrated in FIG. 3.

In addition, in the manufacturing method of the present invention, the multilayer wiring substrate 10 is formed on both sides of the support board in practice, however, according to the embodiment, in order to clarify characteristics of the manufacturing method of the present invention, a case in which the multilayer wiring substrate 10 is formed only on one side of the support board is described.

First, as illustrated in FIG. 5, a support board S with a copper foil on both sides thereof 51 is prepared. The support board S can be configured, for example, a heat-resistance resin plate (for example, bismaleimide-triazine resin plate), a fiber-reinforced resin plate (for example, glass fiber-reinforced epoxy resin), or the like. In addition, as described in detail below, in order to suppress warping of the assembly during manufacture, it is possible to set the thickness of the support board S to 0.4 mm to 1.0 mm. Subsequently, a separation sheet 53 is formed on the copper foil 51 which is formed on both surfaces of the support board S by pressure welding using, for example, a vacuum heat press through a prepreg layer 52 as an adhesion layer.

The separation sheet 53 is formed by, for example, a first metal film 53a and a second metal film 53b, and is configured such that chromium plating or the like is performed between these films, and the separation sheet is separated when an external shearing force acts thereto. In addition, it is possible to form the first metal film 53a and the second metal film 53b using the copper foil.

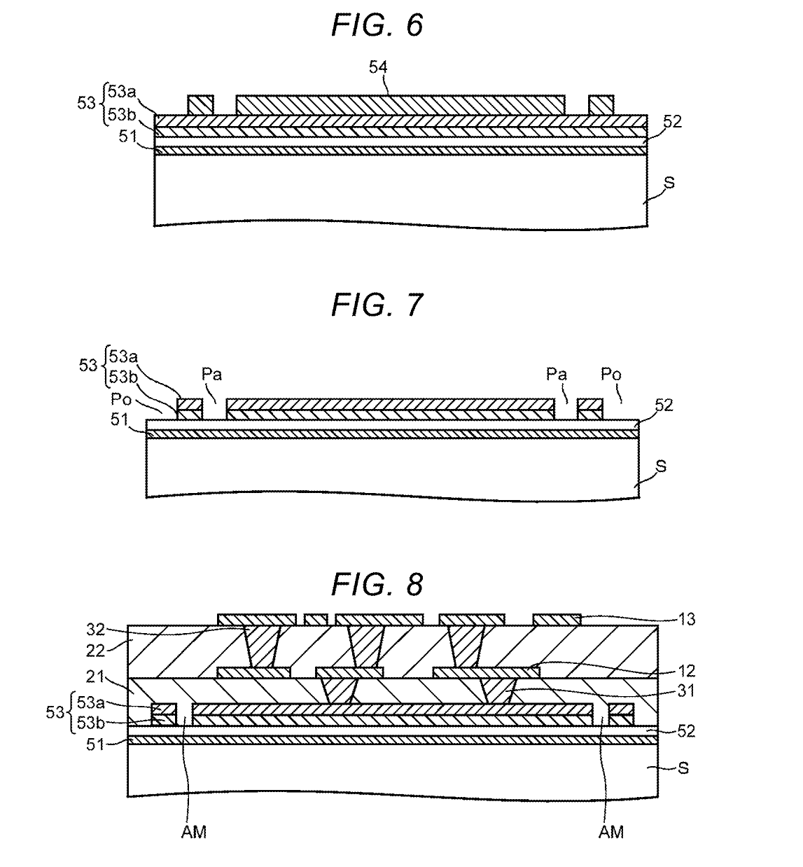

Subsequently, as illustrated in FIG. 6, photosensitive dry films are respectively laminated on separation sheets 53 which are formed on both sides of the support board S, and a mask pattern 54 is formed by exposing and developing the dry films. In the mask pattern 54, openings corresponding to an alignment mark formation portion Pa and an outer periphery decision portion Po are respectively formed.

Subsequently, as illustrated in FIG. 7, an etching process is performed with respect to the separation sheet 53 through the mask pattern 54 on the support board S, and the alignment mark formation portion Pa, and the outer periphery decision portion Po are formed at positions corresponding to the above described openings of the separation sheet 53. In addition, after forming the alignment mark formation portion Pa and the outer periphery decision portion Po, the mask pattern 54 is removed using etching.

In addition, it is preferable to make the surface of the separation sheet 53 rough by performing the etching process with respect to the surface of the separation sheet 53 which is exposed, after removing the mask pattern 54. In this manner, it is possible to increase adherence between the separation sheet 53 and the resin insulating layer to be described later.

Subsequently, as illustrated in FIG. 8, the first resin insulating layer 21 is formed by laminating a resin film on the separation sheet 53, and curing the resin film by performing heating under pressure in a vacuum. In this manner, the surface of the separation sheet 53 is covered with the first resin insulating layer 21, and an opening forming the alignment mark formation portion Pa and a cutout forming the outer periphery decision portion Po are in states of being filled with the first resin insulating layer 21. In this manner, a structure of the alignment mark (AM) is formed at the portion of the alignment mark formation portion Pa.

In addition, since the outer periphery decision portion Po is also covered with the first resin insulating layer 21, it is possible to exclude a disadvantage in which a desired multilayer wiring substrate 10 cannot be manufactured, since the end face of the separation sheet 53 is lifted, for example, by being separated from the prepreg 52 in the separation processing through the separation sheet 53 which is illustrated below, and it is not possible to perform a good separation process.

Subsequently, a via hole is formed by radiating laser light of a predetermined intensity from, for example, a CO₂ gas laser or YAG laser with respect to the first resin insulating layer 21, by performing desmear processing and outline etching with respect to the via hole, and then by performing a roughening process with respect to the first resin insulating layer 21 including the via hole.

When the first resin insulating layer 21 includes filler, since the filler is liberated and remains on the first resin insulating layer 21 in a case of performing the roughening process, water washing is suitably performed.

In addition, it is possible to perform an air blow after performing the water washing. In this manner, it is possible to complement removing of the filler in the process of air blow even when the above described liberated filler is not completely removed by the water washing. Thereafter, pattern plating is performed with respect to the first resin insulating layer 21, and the second conductive layer 12 and the first via conductor 31 are formed.

The second conductive layer 12 and the first via conductor 31 are formed using a semi-additive method as follows. First, after forming an electroless plating film on the first resin insulating layer 21, a resist is formed on the electroless plating film, and electrolytic copper plating is performed at a portion in which the resist is not formed, thereby forming the second conductive layer and the first via conductor. After forming the second conductive layer 12 and the first via conductor 31, the resist is removed by being separated using KOH or the like, and the electroless plating film which is exposed due to removing of the resist is removed using etching.

Subsequently, after performing the roughening process with respect to the second conductive layer 12, a resin film is laminated on the first resin insulating layer 21 so as to cover the second conductive layer 12, and the second resin insulating layer 22 is formed by curing the resin film using heating under pressure in a vacuum. Thereafter, similarly to the case of the first resin insulating layer 21, a via hole is formed in the second resin insulating layer 22, and pattern plating is performed subsequently, thereby forming the third conductive layer 13 and the second via conductor 32. In addition, detailed conditions when forming the third conductive layer 13 and the second via conductor 32 are similar to the case of forming the second conductive layer 12 and the first via conductor 31.

As described above, through the processes illustrated in FIGS. 5 to 8, the first laminated structure 20A includes the first metal film 53a (which eventually becomes the first conductive layer 11), the second conductive layer 12, the third conductive layer 13, the first resin insulating layer 21, the second resin insulating layer 22, the first via conductor 31, and the second via conductor 32. In the first laminated structure 20A, the first via conductor 31 and the second via conductor 32 are formed in the same direction, and specifically, are enlarged in diameter in the upward direction.

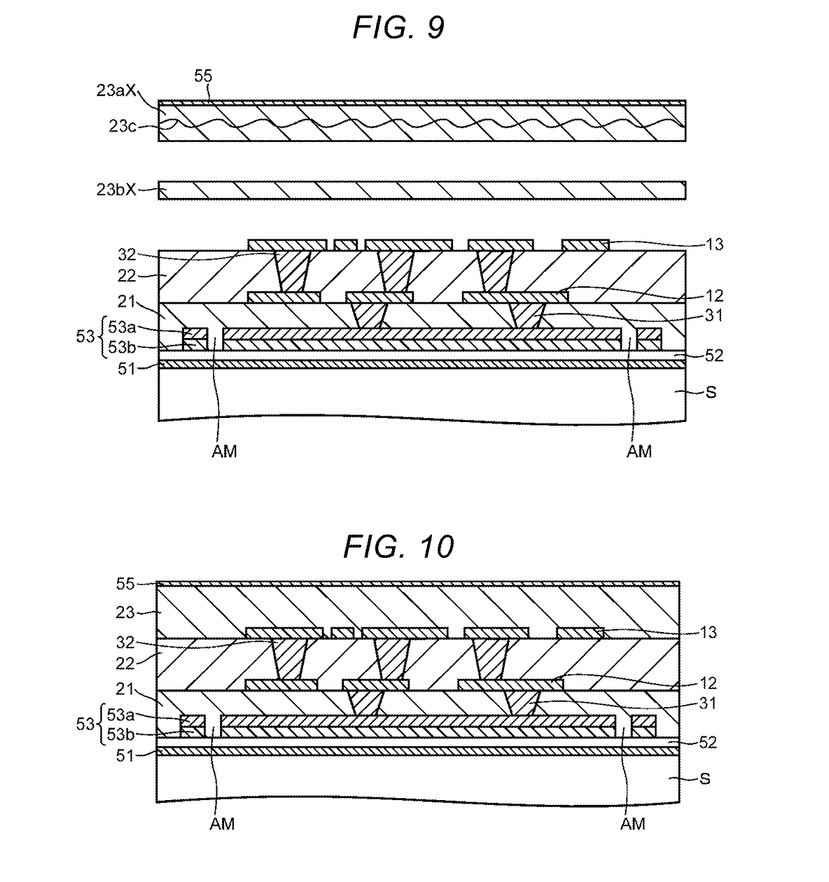

Subsequently, as illustrated in FIG. 9, a resin layer 23bX and a prepreg 23aX (which becomes the reinforcing resin insulating layer), are sequentially arranged on the second resin insulating layer 22 so as to cover the third conductive layer 13. The metal layer 55 is arranged on the upper main surface of the prepreg 23aX. The reinforced fiber 23c is also arranged at the center portion in the thickness direction of the prepreg 23aX. The prepreg 23aX and the resin layer 23bX are then subjected to pressure-welding with respect to the second resin insulating layer 22 by performing vacuum hot pressing at the same time, and are cured. As a result, since the resin layer 23bX becomes the additional resin insulating layer 23b, and the prepreg 23aX includes the reinforced fiber 23c, it becomes the resin insulating layer 23a which forms the original core substrate.

The resin insulating layer 23, which includes the resin insulating layer 23a that includes the reinforced fiber 23c and the additional resin insulating layer 23b, is mainly formed using the same resin material, and since it is difficult to identify the resin insulating layer 23a that includes the reinforced fiber 23c from the additional resin insulating layer 23b, these become the third resin insulating layer 23 (refer to FIG. 10) which form the core substrate in practice. As a result, since the resin insulating layer 23a as the original core substrate is lifted by the thickness of the additional resin insulating layer 23b, the reinforced fiber 23c is located above the center portion II-II in the thickness direction of the third resin insulating layer 23. Accordingly, since the reinforced fiber 23c which is included in the third resin insulating layer 23 is separated from the third conductive layer 13 of the first laminated structure 20A which is located downward, and does not come into contact with the third conductive layer 13, it is possible to suppress the migration of the third conductive layer 13.

According to the embodiment, the reinforced fiber 23c is not particularly limited if the reinforced fiber is located above the center line II-II in the thickness direction of the third resin insulating layer 23, however, in general, the reinforced fiber is located at the center portion of the resin insulating layer 23a which forms the third resin insulating layer 23 in the thickness direction due to the above described manufacturing method. However, if it is the upper part of the center line II-II, the included position is not particularly limited. In addition, according to the embodiment, the center line II-II of the third resin insulating layer 23 in the thickness direction is a line which passes through the center in the length of the third resin insulating layer 23 in the thickness direction which is decided on the lower surface of the fourth resin insulating layer 24 which is adjacent to the upper side of the third resin insulating layer 23, and on the upper surface of the second resin insulating layer 22 which is adjacent to the lower side of the third resin insulating layer 23.

In addition, according to the embodiment, the above described vacuum hot pressing is performed at a temperature of a glass transition point or more of the first resin insulating layer 21 and/or the second resin insulating layer 22, which form the first laminated structure 20A, and it is possible to improve warping of the first laminated structure 20A, and to improve warping at least below the third resin insulating layer 23 in the multilayer wiring substrate 10 which is finally obtained, when forming the third resin insulating layer 23 on the first laminated structure 20A. Accordingly, it is possible to improve warping in the entire multilayer wiring substrate 10.

The thickness of the third resin insulating layer 23 which forms the core substrate can be set to, for example, 0.05 mm to 0.2 mm. Accordingly, when a case in which the thickness of the third resin insulating layer 23 is 0.05 mm is exemplified, the above described reinforced fiber 23c is included upward by 0.025 mm or more from the lower surface of the third resin insulating layer 23.

It is possible to set the thickness of the metal layer 55 to 0.001 mm to 0.035 mm. In addition, the metal layer 55 can be configured by the same metal material as those of the first to seventh conductive layers 11 to 17, for example, a good electric conductor such as copper.

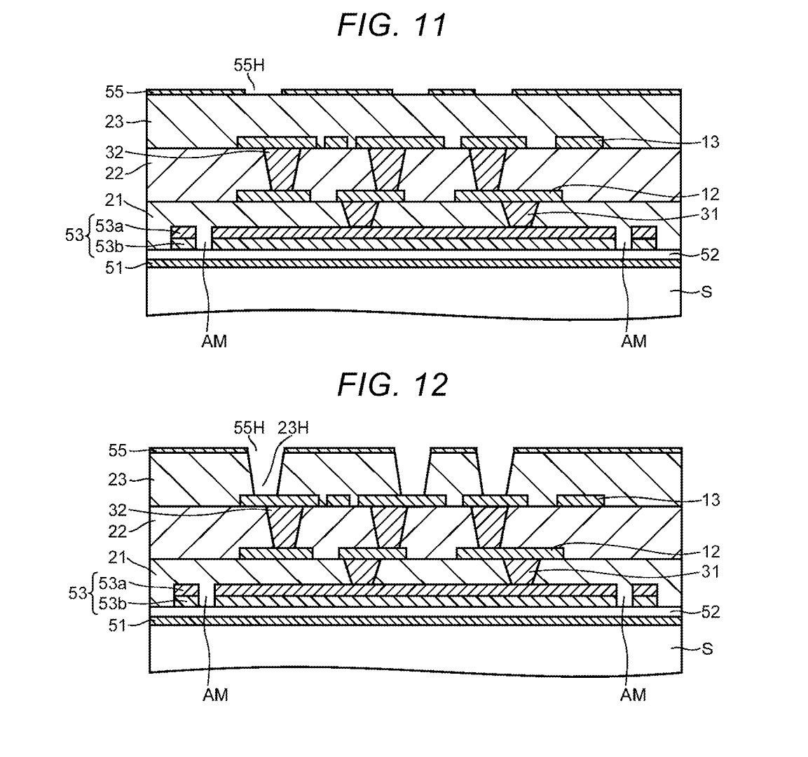

Subsequently, a through hole 23H is formed by radiating laser light to the third resin insulating layer 23 through the opening 55H, and exposes the third conductive layer 13 as illustrated in FIG. 12, after forming the opening 55H by partially removing the metal layer 55 using etching as illustrated in FIG. 11. In this case, in a process illustrated in FIG. 11, in the metal layer 55, since the opening 55H is formed in advance at a portion of the third resin insulating layer 23 at which the through hole 23H is to be formed, the above described laser light is directly radiated to the third resin insulating layer 23 not via the metal layer 55.

Accordingly, when forming the through hole 23H in the third resin insulating layer 23 which forms the core substrate using the laser light, since it is possible to omit a process in which the opening portion is formed in the metal layer 55 using the laser light, it is possible to reduce a radiating energy of the laser light which is necessary when forming the through hole 23H, and to reduce a manufacturing cost of the multilayer wiring substrate 10.

However, it is also possible to omit the process illustrated in FIG. 11. However, in this case, since the opening 55H should be simultaneously formed in the metal layer 55 along with the through hole 23H in the third resin insulating layer 23 using laser beam, the radiating energy of the laser light which is necessary for forming the through hole 23H is increased. For this reason, the manufacturing cost of the multilayer wiring substrate 10 is increased. In addition, it is also possible to omit forming of the metal layer 55.

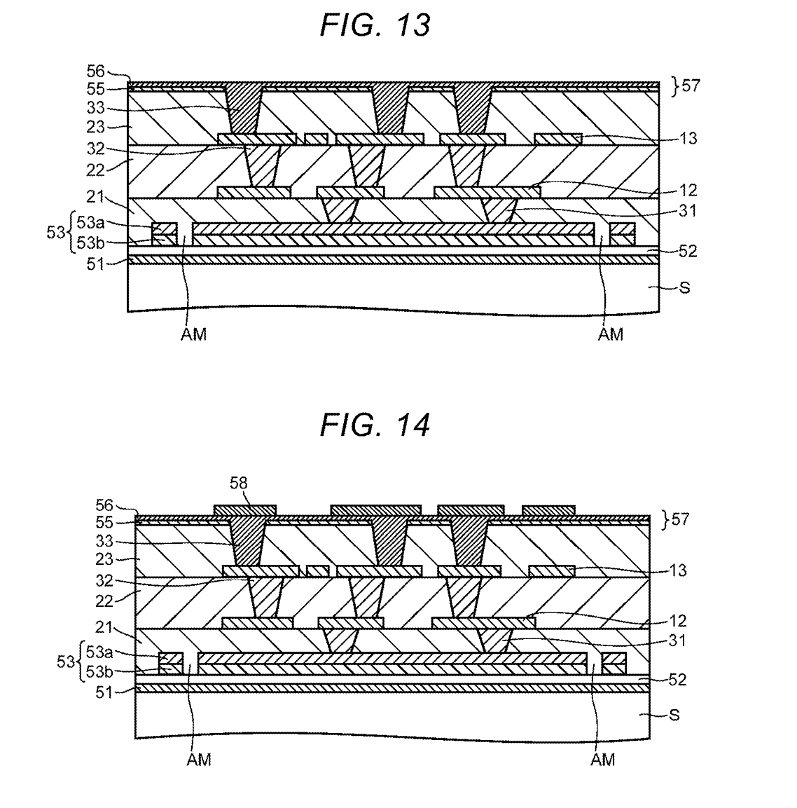

Subsequently, desmear processing and outline etching are appropriately performed with respect to the through hole 23H, a plating ground layer which is not shown is formed on the inner wall surface of the through hole 23H by performing electroless plating, thereafter, and as illustrated in FIG. 13, the through hole 23H is buried using plating by performing a so-called filled via plating process (electrolytic plating). In this case, since the plating layer functions as the third via conductor 33 which electrically connects the first laminated structure 20A, which is formed on the lower surface side of the third resin insulating layer 23, and the second laminated structure 20B, which is formed on the upper surface side of the third resin insulating layer 23, the length of wiring for electrically connecting these laminated structures becomes short, and it is possible to suppress deterioration in a transmission performance of a high frequency signal.

In addition, in a manufacturing method of a multilayer wiring substrate having a core substrate in the related art, it is necessary to provide a through hole conductor in the core substrate in order to electrically connect laminated structures which is formed on both surfaces of the core substrate. For this reason, it is essential to make the length of wiring for electrically connecting the laminated structure long, and there is a concern that a transmission performance of a high frequency signal may be deteriorated.

In addition, since a plating layer 56 is formed on the metal layer 55, as well, due to the above described filled via plating process which is performed, a metal laminated body which is formed by laminating the plating layer 56 on the metal layer 55 is denoted by a reference numeral 57. As described above, since it is possible to form the metal layer 55 using copper, and it is possible to form the plating layer 56 using copper as well, the plating layer 56 can have the same function as that of the metal layer 55, and it is possible to make the metal laminated body 57 as a single metal layer. When not forming the metal layer 55, the reference numeral 57 denotes the plating layer.

The third via conductor 33 which is formed so as to penetrate the third resin insulating layer 23 forming the core substrate is expanded in diameter in the same direction as the first via conductor 31 and the second via conductor 32 of the first laminated structure 20A, and specifically, is expanded in diameter upward.

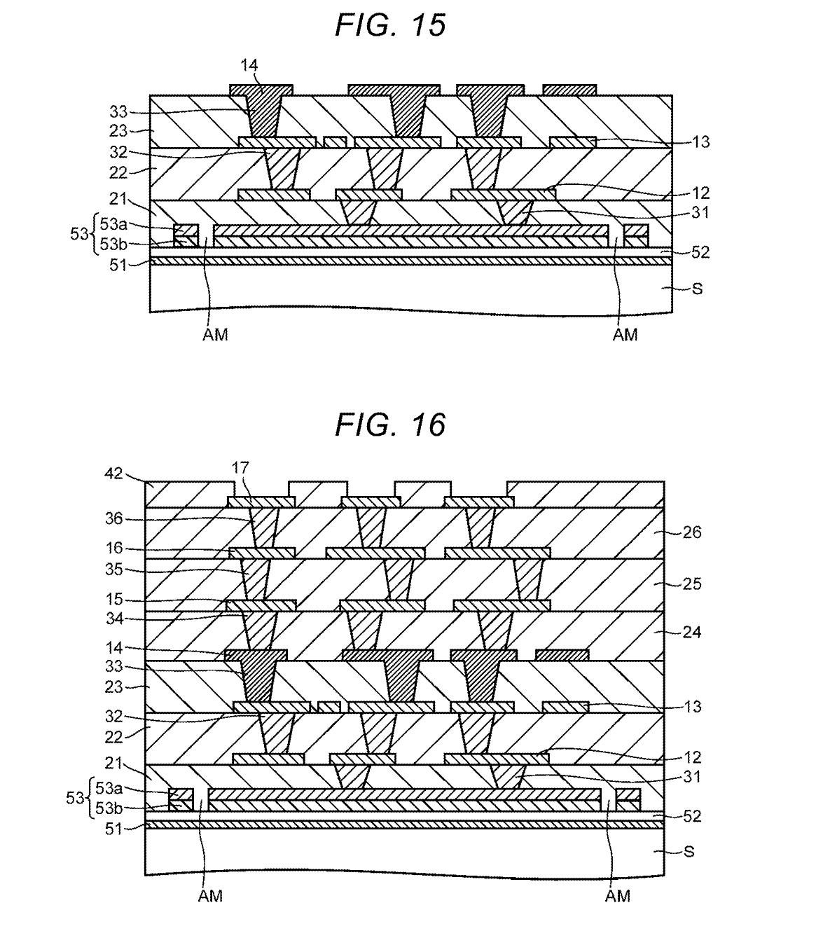

Subsequently, as illustrated in FIG. 14, a resist pattern 58 is formed on the metal laminated body (metal layer) 57, and as illustrated in FIG. 15, the metal laminated body (metal layer) 57 is subjected to etching through the resist pattern 58 subsequently, and the fourth conductive layer 14 is formed on the third resin insulating layer 23 by removing the resist pattern 58, thereafter.

Subsequently, after performing a roughening process with respect to the fourth conductive layer 14, a resin film is laminated on the third resin insulating layer 23 so as to cover the fourth conductive layer 14 as illustrated in FIG. 16, and a fourth resin insulating layer 24 is formed by curing the resin film using press heating under pressure in a vacuum. Thereafter, similarly to the case of the first resin insulating layer 21, a via hole is formed in the fourth resin insulating layer 24, and a fifth conductive layer 15, and a fourth via conductor 34 are formed by performing a pattern plating, subsequently. In addition, detailed conditions when forming the fifth conductive layer 15 and the fourth via conductor 34 are the same as those when forming the second conductive layer 12 and the first via conductor 31.

In addition, as illustrated in FIG. 16, a fifth resin insulating layer 25 and a sixth resin insulating layer 26 are sequentially formed similarly to the fourth resin insulating layer 24, and further, a sixth conductive layer 16, a fifth via conductor 35, a seventh conductive layer 17, and a sixth via conductor 36 are formed similarly to the fifth conductive layer 15 and the fourth via conductor 34, respectively, in the fifth resin insulating layer 25 and the sixth resin insulating layer 26.

The fourth to seventh conductive layers 14 to 17, the fourth to sixth resin insulating layers 24 to 26, and the fourth to sixth via conductors 34 to 36 form the second laminated structure 20B. In addition, the fourth to sixth via conductors 34 to 36 which form the second laminated structure 20B are expanded in diameter in the same direction as the third via conductor 33 which is formed so as to penetrate the third resin insulating layer 23 which forms the core substrate, and the first and second via conductors 31 and 32 which are formed so as to penetrate the first and second resin insulating layers 21 and 22 of the first laminated structure 20A in the thickness direction, and specifically are expanded in diameter upward.

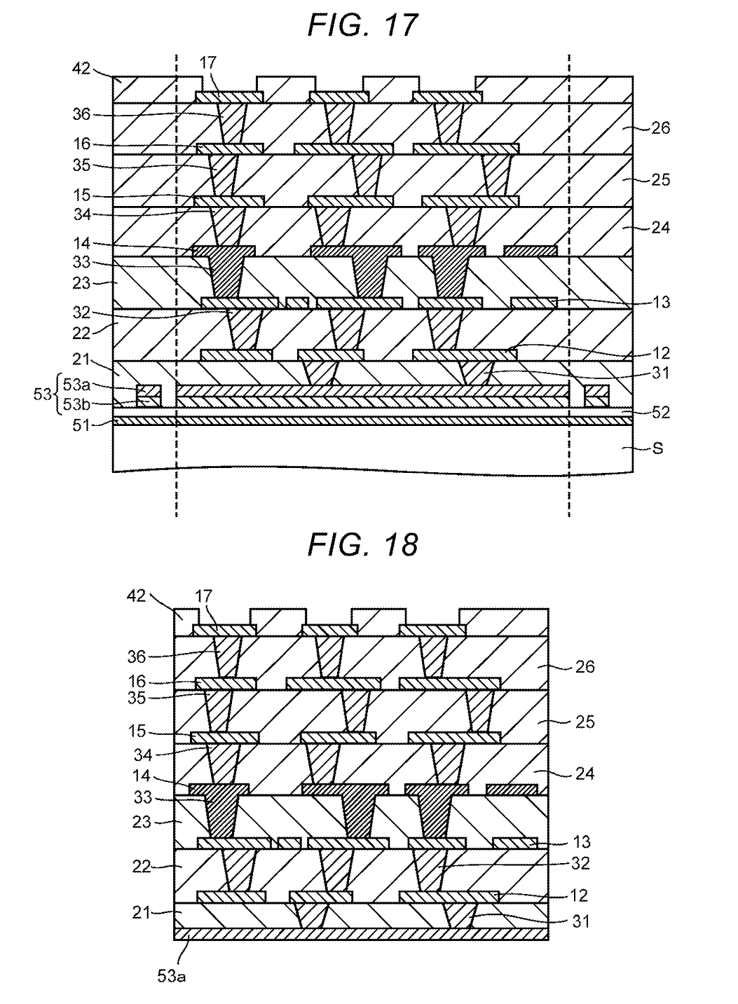

Subsequently, as illustrated in FIG. 17, the laminated body which includes the first laminated structure 20A, the third resin insulating layer 23, and the second laminated structure 20B which are obtained through the above described processes is cut along a cutting line which is set slightly inside the outer periphery decision portion Po, and an unnecessary outer peripheral portion is removed.

Subsequently, as illustrated in FIG. 18, the first metal film 53a and the second metal film 53b which configure the separation sheet 53 of a multilayer wiring laminated body which is obtained through the process illustrated in FIG. 17 are separated at the separation interface, and the support board S is removed from the above described multilayer wiring laminated body.

Subsequently, etching is performed with respect to the first metal film 53a of the separation sheet 53 which is remaining at the lower side of the multilayer wiring laminated body which is obtained in FIG. 18, and the first conductive layer 11 is formed. Thereafter, the multilayer wiring substrate 10 which is illustrated in FIG. 3 is obtained by forming the first resist layer 41 by partially exposing the first conductive layer 11.

According to the embodiment, the laminated structure in which at least one conductive layer and at least one resin insulating layer are laminated on the support board is formed. Ina manufacturing method of a so-called coreless multilayer wiring substrate, the core substrate is also laminated along with the above described laminated structure, and the additional laminated structure having the same configuration is further laminated on the core substrate. As a manufacturing method of the coreless multilayer wiring substrate, it has a configuration in which, after forming the laminated structure on the support board as described above, finally, in order to remove the support board, the core substrate is inserted into the laminated structure which is formed by at least one conductive layer and at least one resin insulating layer, that is, the multilayer wiring substrate having the core substrate remains.

According to the embodiment, since the manufacturing method of the coreless multilayer wiring substrate is used when manufacturing the multilayer wiring substrate 10 having the core substrate (third resin insulating layer 23), in the manufacturing process, the first and second laminated structures 20A and 20B and the core substrate are formed on the support board S. Accordingly, even when the thickness of the core substrate is made small, the strength of the assembly in the manufacturing process is not decreased by making the thickness of the support board S sufficiently large.

Accordingly, it is possible to transport the assembly horizontally in the manufacturing process, and to avoid a problem in that the assembly comes into contact with transport equipment when being transported, and the core substrate or the assembly is damaged. In addition, it is also possible to avoid a problem in that, when performing a predetermined manufacturing process with fixing the assembly, the assembly is warped so that it is difficult to accurately perform a process, for example, a plating process, or the like. For this reason, it is possible to obtain a multilayer wiring substrate 10 having a thin core substrate, with a high yield, and to miniaturize the multilayer wiring substrate 10 having the core substrate.

The method according to the embodiment, is not limited to manufacturing of the multilayer wiring substrate including the core substrate which has a structure in which the yield in manufacturing is decreased, since the core substrate is thin, and the core substrate or assembly in the manufacturing process is warped in an ordinary manufacturing method, and can be applied to a case in which the core substrate is thick, and it is possible to manufacture the multilayer wiring substrate including the core substrate, with a high yield, even in the ordinary manufacturing method. However, in this case, it is difficult to obtain the characteristic operation effects of the embodiment.

In addition, according to the embodiment, a so-called subtractive method is used when forming the fourth conductive layer 14, however, it is also possible to form the fourth conductive layer using a semi-additive method instead of such a subtractive method.

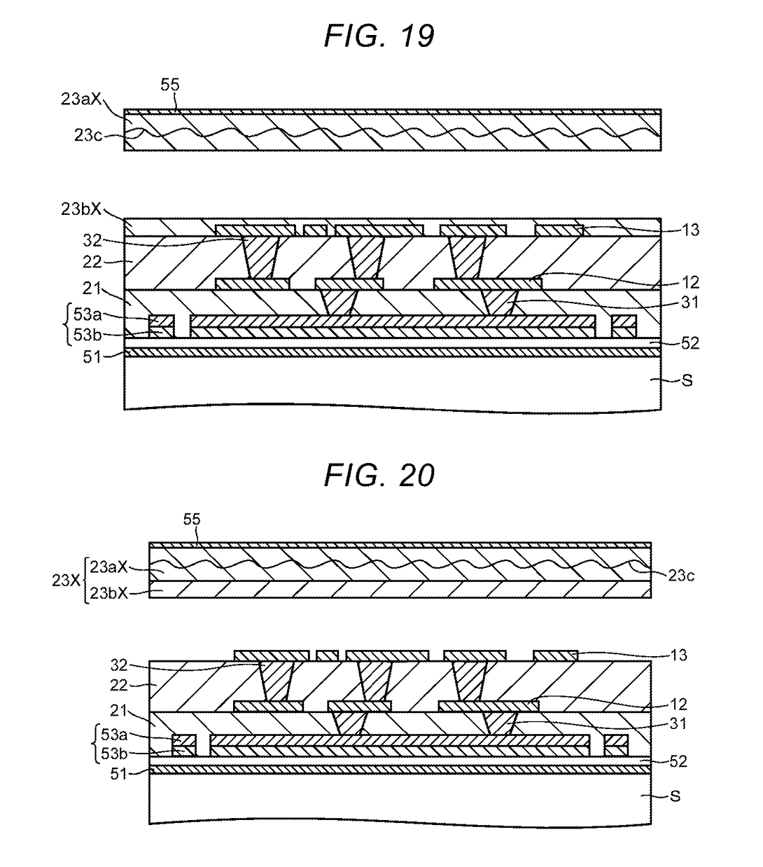

FIGS. 19 and 20 are diagrams which illustrate modified examples of the manufacturing method according to the embodiment. In the above described embodiment, as illustrated in FIG. 9, the resin layer 23bX and the prepreg 23aX including the reinforced fiber 23c at the center portion in the thickness direction are sequentially arranged on the first laminated structure 20A (second resin insulating layer 22). The metal layer 55 is arranged on the upper main surface of the prepreg 23aX. The resin layer 23bX and the prepreg 23aX are subjected to pressure welding by performing vacuum hot pressing at the same time, and are cured. As a result, the third resin insulating layer 23 in which the additional resin insulating layer 23b and the resin insulating layer 23a (the original core substrate) are laminated has been formed.

On the other hand, in the example illustrated in FIG. 19, the resin insulating layer 23bX is laminated on the first laminated structure 20A, and is made as the additional resin insulating layer 22b by performing the vacuum hot pressing. The metal layer 55 is arranged on the top main surface on the prepreg 23aX, which includes the reinforced fiber 23c at the center in the thickness direction thereof, and these are laminated to form the resin insulating layer 23a by performing the vacuum hot pressing. The resin insulating layers 23a, 23b thereby form the third resin insulating layer 23 in this manner.

In addition, in the example illustrated in FIG. 20, the third resin insulating layer 23 is formed by arranging the metal layer 55 on the top main surface of the prepreg 23aX that includes the reinforced fiber 23c at the center in the thickness direction thereof, and then laminating the prepreg 23aX to the resin insulating layer 23bX. The obtained laminated body (prepreg) 23X is then laminated on the first laminated structure 20A and is subject to the vacuum hot pressing.

In both cases, only the formation order of the resin insulating layer 23a and the additional resin insulating layer 23b which form the original core substrate is different, and the third resin insulating layer 23 which is finally obtained is formed by the additional resin insulating layer 23b which is located below the resin insulating layer 23a which is located thereon.

According to both the manufacturing methods, since the resin insulating layer 23a which is part of the original core substrate is also lifted by the thickness of the additional resin insulating layer 23b, the reinforced fiber 23c is located above the center line II-II in the thickness direction of the third resin insulating layer 23. As a result, since the reinforced fiber 23c which is included in the third resin insulating layer 23 is separated from and does not come into contact with the third conductive layer 13 of the first laminated structure 20A, it is possible to suppress the migration of the third conductive layer 13.

Hitherto, the present invention has been described in detail by describing specific examples, however, the present invention is not limited to the above described contents, and can be variously modified, or changed without departing from the scope of the present invention.

In the above described embodiment, the manufacturing method of the multilayer wiring substrate which obtains the multilayer wiring substrates 10 and 10′ by forming the first and second resist layers 41 and 42 after removing the support board S has been described, however, when further multilayering is attempted, it is also preferable to include a process in which a conductive layer and a resin insulating layer are further laminated on the surfaces of the first and second laminated structures 20A and 20B after removing the support board S.

In the above described embodiment, the manufacturing method of the multilayer wiring substrate has been described in which the conductive layer and the resin insulating layer are sequentially laminated from the conductive layer side which functions as a rear surface land for connecting to a mother board, toward the conductive layer side which functions as the pad (FC pad) for performing flip chip connecting of the semiconductor element, or the like, however, the order of laminating is not limited, and the conductive layer and the resin insulating layer may be laminated from the conductive layer side which functions as the FC pad toward the conductive layer side which functions as the rear surface land.

In the above described embodiment, an embodiment has been described in which the resin insulating layer 23a configuring the third resin insulating layer 23, and the additional resin insulating layer 23b are configured by mainly using the same resin material, however, physical properties, or the like of the resin material is not particularly limited, and it may be configured using an additional resin insulating layer 23b having a higher insulation property than that of the resin insulating layer 23a in order to suppress the migration of the conductive layer.

What is claimed is:

1. A multilayer wiring substrate comprising:
a first laminated structure that includes at least one conductive layer and at least one resin insulating layer;
a core substrate that includes a reinforced fiber and that is laminated on the first laminated structure;
a second laminated structure that includes at least one conductive layer and at least one resin insulating layer and that is formed on the core substrate; and
a plurality of via conductors that penetrate the at least one resin insulating layer of the first laminated structure, the core substrate, and the at least one resin insulating layer of the second laminated structure,
wherein the plurality of via conductors all expand in diameter in the same direction, and
wherein the reinforced fiber is located above a center of the core substrate in a thickness direction.

2. A method of manufacturing a multilayer wiring substrate comprising:
forming, on a support board, a first laminated structure that includes at least one conductive layer and at least one resin insulating layer;
forming, on the first laminated structure, a core substrate that includes a reinforced fiber by laminating the core substrate on the first laminated structure;
forming, on the core substrate, a second laminated structure that includes at least one conductive layer and at least one resin insulating layer; and
forming a plurality of via conductors that penetrate the at least one resin insulating layer of the first laminated structure, the core substrate, and the at least one resin insulating layer of the second laminated structure,
wherein the plurality of via conductors are all formed to expand in diameter in the same direction, and
wherein the reinforced fiber is located above a center of the core substrate in a thickness direction.

3. The method of manufacturing a multilayer wiring substrate according to claim 2, wherein forming the core substrate comprises, in the following order:
1) arranging a reinforced resin insulating layer that includes the reinforced fiber and an additional resin insulating layer on the first laminated structure; and
2) subjecting the reinforced fiber and the additional resin insulating layer to a pressure welding process at the same time.

4. The method of manufacturing a multilayer wiring substrate according to claim 2, wherein forming the core substrate comprises:
laminating an additional resin insulating layer on the first laminated structure; and
laminating a reinforced resin insulating layer that includes the reinforced fiber on the laminated additional resin insulating layer.

5. The method of manufacturing a multilayer wiring substrate according to claim 2, wherein forming the core substrate comprises:
forming a laminated body by laminating a reinforced resin insulating layer that includes the reinforced fiber and an additional resin insulating layer in this order; and
laminating the laminated body on the first laminated structure so that the additional resin insulating layer becomes a lower side of the core substrate.
